(19) United States
(12) Patent Application Publication
(10) Pub. No.: US 2025/0179638 A1
(43) Pub. Date: Jun. 5, 2025

(54) SHOWERHEAD ASSEMBLY AND SUBSTRATE PROCESSING SYSTEMS FOR IMPROVING DEPOSITION THICKNESS UNIFORMITY

(71) Applicant: LAM RESEARCH CORPORATION, Fremont, CA (US)

(72) Inventors: Eli JEON, Sherwood, OR (US); Daniel BOATRIGHT, Estacada, OR (US); Philip CHEN, Lake Oswego, OR (US); Debotosh PODDAR, Durgapur (IN); Kyle Watt HART, Beaverton, OR (US); Douglas Walter AGNEW, Portland, OR (US); Kashyap SUBRAMANYA, Bangalore (IN)

(21) Appl. No.: 18/845,821

(22) PCT Filed: Apr. 25, 2022
(86) PCT No.: PCT/US2022/026104

§ 371 Date: Sep. 10, 2024

Related U.S. Application Data
(60) Provisional application No. 63/325,112, filed on Mar. 29, 2022.
(60) Provisional application No. 63/323,710, filed on Mar. 25, 2022.

(51) Int. Cl. C23C 16/455; C23C 16/56; H01J 37/32

(52) U.S. Cl. CPC C23C 16/45565; C23C 16/45591; C23C 16/56; H01J 37/3244; H01J 37/32633

(57) ABSTRACT

A showerhead assembly includes a showerhead with an upper portion including a gas channel extending in a first direction and having a first width in a second direction. A lower portion is connected to the upper portion and includes a faceplate including a plurality of gas through holes extending vertically through the faceplate in the first direction and a baffle plate arranged on a plurality of posts above the faceplate and below an outlet of the gas channel. A gas plenum is defined between the upper portion and the lower portion, extends in the second direction, and is in fluid communication with the gas channel. The showerhead assembly includes a back side gas system to supply gas to a bellows volume defined by a bellows arranged around an upper portion of the showerhead. First and second annular gas flows are supplied across an outer surface of the showerhead.

### CROSS-REFERENCE TO RELATED APPLICATIONS

This application claims the benefit of U.S. Provisional Application No. 63/323,710, filed on Mar. 25, 2022 and 63/325,112, filed on Mar. 29, 2022. The entire disclosures of the applications referenced above are incorporated herein by reference.

### FIELD

The present disclosure relates to substrate processing systems and more particularly to showerheads and showerhead assemblies for substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems are used to perform treatments on substrates such as semiconductor wafers. Examples of the treatments include deposition, etching, cleaning and/or other treatments. During deposition of film onto the substrate, process gases are delivered to the processing chamber and plasma may be struck in the processing chamber to initiate chemical reactions.

It is important for the deposition process to be uniform from one substrate to another and from one portion of the substate to another. For example, some deposition processes may produce film having a thickness that varies from the center of the substrate to the edge of the substrate. For example, the substrate can be center low or center high relative to the edges. Non-uniform film thickness can be caused by variations in gas delivery, variable substrate temperature, variations in plasma conditions across the substrate, and/or other factors.

### SUMMARY

A showerhead for a substrate processing system includes an upper portion including a gas channel extending in a first direction and having a first width in a second direction transverse to the first direction. A lower portion is connected to the upper portion and includes a faceplate including a plurality of gas through holes extending vertically through the faceplate in the first direction and a baffle plate arranged on a plurality of posts above the faceplate and below an outlet of the gas channel. The baffle plate includes a plurality of baffle orifices and has a second width in the second direction that is in a range from 1.25 to 3 times the first width. A gas plenum is defined between the upper portion and the lower portion, extending in the second direction, and in fluid communication with the gas channel.

In other features, each of the plurality of baffle orifices is misaligned with ones of the plurality of gas through holes that are located below the baffle plate in the first direction. The plurality of baffle orifices is arranged symmetrically relative to a center of the baffle plate. The second width is in a range from 1.75 to 2.5 times the first width.

In other features, the plurality of gas through holes has a first diameter and the plurality of baffle orifices has a second diameter that is greater than the first diameter. The second diameter is in a range from 1.2 to 6 times greater than the first diameter. The second diameter is in a range from 1.5 to 3 times greater than the first diameter.

In other features, the upper portion includes a stem portion, a first cone-shaped portion extending from the stem portion, and a second cone-shaped portion extending from the first cone-shaped portion and including a radially outer edge attached to the lower portion.

In other features, a side surface of the first cone-shaped portion forms a first acute angle relative to a side surface of the stem portion. A side surface of the second cone-shaped portion forms a second acute angle relative to a side surface of the stem portion. The first acute angle is less than the second acute angle.

In other features, P posts are connected between the faceplate and the second cone-shaped portion of the upper portion, wherein P is an integer greater than one. P is in a range from 8 to 24. P is equal to 12. The P posts are arranged in a circle. The P posts are arranged between a first radius corresponding to a radially inner edge of the second cone-shaped portion and a second radius corresponding to a radially outer edge of the second cone-shaped portion.

In other features, the gas channel has a first radius. A substrate-facing surface of the lower portion includes a rounded portion extending from the first radius to a second radius. A first horizontal portion extends from the second radius to a third radius. A tapered portion extends from the third radius to a fourth radius. A second horizontal portion extends from the fourth radius to a fifth radius.

In other features, the third radius is in a range from 0.75 to 2.5 times the second width. The baffle plate is arranged between 25% and 75% of a distance between the first horizontal portion and the faceplate in the first direction.

In other features, P access holes pass through the second cone-shaped portion of the upper portion. P posts connect the faceplate to the second cone-shaped portion and extend into the P access holes, wherein P is an integer greater than one. At least one of the baffle orifices at least partially overlaps at least one of the gas through holes in the first direction. At least one of the baffle orifices fully overlaps at least one of the gas through holes in the first direction.

In other features, the gas through holes in the faceplate are arranged in a first zone and a second zone. First ones of the plurality of gas through holes in the first zone have a first hole density. Second ones of the plurality of gas through holes arranged in the second zone have a second hole density. The second hole density is greater than the first hole density.

In other features, the first zone extends to a first radius, the second zone extends from the first radius to a second radius, and the first radius is greater than or equal to 0.7 times the second radius.

In other features, a back side gas system is configured to supply gas in a downward and radially outward direction along the stem portion, the first cone-shaped portion, and the second cone-shaped portion.

A substrate processing system comprises the showerhead and a processing chamber including an upper surface defining a cavity. An annular support is arranged around the stem portion and in the cavity of the upper surface and including a radially inner surface and a radially outer surface. A first annular gap is formed between the radially outer surface of the annular support and the cavity in the upper surface of the processing chamber. A second annular gap is formed between the radially inner surface of the annular support and the stem portion. The back side gas system supplies the gas to the first annular gap and the second annular gap.

A method for depositing film on a substrate includes delivering process gas to an exposed surface of the substrate using a showerhead arranged in the processing chamber. The showerhead comprises an upper portion including a gas channel configured to receive the process gas, extending in a first direction and having a first width in a second direction transverse to the first direction; a lower portion comprising a faceplate with a plurality of gas through holes extending through the faceplate in the first direction; and a gas plenum defined between the upper portion and the lower portion and extending in the second direction. The method includes redirecting process gas exiting the gas channel using a baffle plate that is located below the gas channel in the gas plenum and above the faceplate and includes a plurality of baffle orifices extending through the baffle plate in the first direction. A first portion of the process gas is redirected from the first direction to the second direction by portions of the baffle plate without the plurality of orifices. A second portion of the process gas passes through the plurality of orifices of the baffle plate and through ones of the plurality of gas through holes arranged below the baffle plate. The baffle plate has a second width in the second direction that is in a range from 1.25 to 3 times the first width.

In other features, the process gas includes at least one of a reactant and a precursor. The method includes exposing the substrate to the at least one of the precursor and the reactant to form a dielectric material. The method includes treating the dielectric material to a densification plasma to form a densified dielectric material.

In other features, the baffle orifices are misaligned with ones of the plurality of gas through holes that are located below the baffle plate in the first direction. The plurality of baffle orifices are arranged symmetrically relative to a center of the baffle plate. The second width is in a range from 1.75 to 2.5 times the first width. The plurality of gas through holes has a first diameter and the plurality of baffle orifices has a second diameter that is greater than the first diameter. The second diameter is in a range from 1.2 to 6 times greater than the first diameter. The second diameter is in a range from 1.5 to 3 times greater than the first diameter.

In other features, the upper portion includes a stem portion, a first cone-shaped portion extending from the stem portion, and a second cone-shaped portion extending from the first cone-shaped portion and including a radially outer portion attached to the lower portion.

In other features, the first cone-shaped portion forms a first acute angle between and a side surface of the stem portion. A side surface of the second cone-shaped portion forms a second acute angle between a side surface of the stem portion, wherein the first acute angle is less than the second acute angle.

In other features, P posts are connected between the faceplate and the second cone-shaped portion, wherein P is in a range from 8 to 24. P is equal to 12. The P posts are arranged between a first radius corresponding to a radially inner edge of the second cone-shaped portion and a second radius corresponding to a radially outer edge of the second cone-shaped portion.

In other features, the gas channel has a first radius. A substate-facing surface of the upper portion includes a rounded portion extending from the first radius to a second radius; a first horizontal portion extending from the second radius to a third radius; a tapered portion extending from the third radius to a fourth radius; and a second horizontal portion extending from the fourth radius to a fifth radius.

In other features, the third radius is in a range from 0.75 to 2.5 times the second width. The baffle plate is arranged between 25% and 75% of a distance between the first horizontal portion and the faceplate in the first direction. P access holes pass through the second cone-shaped portion of the upper portion and P posts connect the faceplate to the second cone-shaped portion and extend into the P access holes, wherein P is an integer greater than one. At least one of the baffle orifices at least partially overlaps at least one of the gas through holes in the first direction. At least one of the baffle orifices fully overlaps at least one of the gas through holes in the first direction.

In other features, first ones of the plurality of gas through holes are arranged in a first zone with a first hole density; and second ones of the plurality of gas through holes are arranged in a second zone with a second hole density, wherein the second hole density is greater than the first hole density.

In other features, the first zone extends to a first radius; the second zone extends from the first radius to a second radius; and the first radius is greater than or equal to 0.7 times the second radius.

In other features, the method includes supplying gas in a downward and radially outward direction along the stem portion, the first cone-shaped portion, and the second cone-shaped portion. The film comprises a dielectric film. A showerhead for a substrate processing system includes an upper portion including a stem portion, a first cone-shaped portion including a side surface extending from the stem portion at a first acute angle relative to a side surface of the stem portion, a second cone-shaped portion extending from the first cone-shaped portion and including a side surface forming a second acute angle relative to the side surface of the stem portion, and a gas channel extending in a first direction through the upper portion, wherein the second acute angle is greater than the first acute angle. A lower portion includes a radially outer edge connected to the upper portion, a faceplate including a plurality of gas through holes extending in the first direction through the faceplate, and a baffle plate arranged on a plurality of posts between the faceplate and the gas channel and including a plurality of baffle orifices extending through the baffle plate in the first direction. A gas plenum is defined between the upper portion and the lower portion and extending in a second direction transverse to the first direction. A back side gas system is configured to supply gas along the stem portion, the first cone-shaped portion, and the second cone-shaped portion during substrate processing.

A showerhead for a substrate processing system includes an upper portion including a stem portion, a first cone-shaped portion extending from the stem portion, a second cone-shaped portion extending from the first cone-shaped portion. A gas channel extends through the upper portion in a first direction and having a first radius. A lower portion includes a radially outer edge connected to the upper portion, a faceplate including a plurality of gas through holes extending through the faceplate in the first direction, and a baffle plate arranged on a plurality of posts above the faceplate and including a plurality of baffle orifices extending through the baffle plate. A gas plenum is defined between a first surface of the upper portion and the lower portion and extending in a second direction transverse to the first direction. The first surface of the upper portion includes a rounded portion extending from the first radius to a second radius, a first horizontal portion extending from the second radius to a third radius, a tapered portion extending at an acute angle from the third radius to a fourth radius, and a second horizontal portion extending from the fourth radius to a fifth radius.

A showerhead for a substrate processing system includes an upper portion including a stem portion, a first cone-shaped portion including a side surface extending from the stem portion at a first acute angle relative to a side surface of the stem portion, a second cone-shaped portion extending from the first cone-shaped portion and including a side surface forming a second acute angle relative to the side surface of the stem portion, and a gas channel extending through the upper portion in a first direction, wherein the second acute angle is greater than the first acute angle. A lower portion includes a radially outer edge connected to the upper portion, a faceplate including a plurality of gas through holes extending through the faceplate in the first direction, and a baffle plate arranged on a plurality of posts above the faceplate and including a plurality of baffle orifices extending through the baffle plate faceplate in the first direction. A gas plenum is defined between the upper portion and the lower portion. The faceplate includes a first zone that extends to a first radius and a second zone that extends from the first radius to a second radius, first ones of the plurality of gas through holes arranged in the first zone have a first hole density, second ones of the plurality of gas through holes arranged in the second zone have a second hole density, and the second hole density is greater than the first hole density.

A substrate processing system includes a processing chamber including an upper chamber surface defining a first cavity. A showerhead assembly includes a showerhead with an upper portion, a lower portion including a faceplate, and a gas plenum arranged between the upper portion and the lower portion. A first annular support member is arranged in the first cavity and defines a second cavity configured to receive the upper portion of the showerhead. The first annular support member defines a first annular gap located between a radially inner surface of the second cavity and a radially outer surface of the upper portion of the showerhead. A second annular gap is located between the radially outer surface of the first annular support member and a radially inner surface of the first cavity. Back side gas is split by the first annular support member into a first gas flow into the first annular gap and a second gas flow into the second annular gap.

In other features, the first annular support member includes an upper annular portion and a lower annular portion extending downwardly from the upper annular portion. The second cavity passes through the upper annular portion and the lower annular portion. The upper annular portion has an outer diameter that is greater than an outer diameter of the lower annular portion.

In other features, the first annular support member includes a plurality of channels passing from a radially inner surface of the first annular support member to a radially outer surface of the first annular support member. The second gas flow passes through the plurality of channels to the second annular gap. A first protrusion extends radially inwardly from the radially inner surface of the first annular support member to restrict flow of gas into the first annular gap.

A second annular support member includes a gas channel. An annular support plate is connected to the second annular support member and includes an annular opening in fluid communication with an outlet of the gas channel of the second annular support member. A first protrusion extends radially inwardly from a radially inner surface of the annular support plate towards an outer surface of the first annular support member to restrict flow of gas from the gas channel into the first annular gap and the second annular gap.

In other features, the first gas flow through the first annular gap is less than the second gas flow through the second annular gap. The second gas flow is in a range from 60% to 90% of gas flowing through the first annular gap and the second annular gap and the first gas flow is in a range from 10% to 40% of the gas flowing through the first annular gap and the second annular gap. The second gas flow is in a range from 68% to 76% of gas flowing through the first annular gap and the second annular gap and the first gas flow is in a range from 24% to 32% of the gas flowing through the first annular gap and the second annular gap.

In other features, a tilt mechanism is configured to tilt the showerhead relative to the first annular support member. When the tilt mechanism tilts the showerhead relative to a centered position, the first annular gap is narrowed at a first radial location. A bellows is arranged between a first surface of the first annular support member and a second surface of the annular support plate.

In other features, the upper portion of the showerhead includes a stem portion, a first cone-shaped portion extending from the stem portion, and a second cone-shaped portion extending from the first cone-shaped portion. The first gas flow and the second gas flow are directed across the stem portion, the first cone-shaped portion, and the second cone-shaped portion.

In other features, the first cone-shaped portion includes a side surface extending from the stem portion at a first acute angle relative to a side surface of the stem portion. The second cone-shaped portion extends from the first cone-shaped portion and includes a side surface forming a second acute angle relative to the side surface of the stem portion. The second acute angle is greater than the first acute angle.

In other features, the faceplate includes a plurality of gas through holes extending vertically through the faceplate in a first direction. The upper portion of the showerhead includes a gas channel extending in the first direction and having a first width in a second direction transverse to the first direction. A baffle plate is arranged on a plurality of posts above the faceplate and below an outlet of the gas channel, wherein the baffle plate includes a plurality of baffle orifices and has a second width in the second direction that is in a range from 1.25 to 3 times the first width.

In other features, each of the plurality of baffle orifices is misaligned with ones of the plurality of gas through holes that are located below the baffle plate in the first direction. The plurality of baffle orifices is arranged symmetrically relative to a center of the baffle plate. The second width is in a range from 1.75 to 2.5 times the first width. The plurality of gas through holes has a first diameter and the plurality of baffle orifices has a second diameter that is greater than the first diameter. The second diameter is in a range from 1.2 to 6 times greater than the first diameter. The second diameter is in a range from 1.5 to 3 times greater than the first diameter.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a substrate processing system including a showerhead with a porous baffle plate according to embodiments of the present disclosure;

FIG. 2A is side cross-sectional view of a commercialized showerhead with a solid baffle plate arranged within;

FIG. 2B is a plan view of a solid baffle plate arranged above a faceplate of a gas plenum of the showerhead depicted in 2A;

FIG. 3 is a graph illustrating non-uniform thickness of film deposited using the showerhead shown in FIGS. 2A and 2B;

FIG. 4A is a side cross-sectional view of an example of a showerhead with a baffle plate including baffle orifices according to the present disclosure;

FIG. 4B is a side view of an example of the showerhead of FIG. 4A;

FIG. 4C is a side cross-sectional view of another example of a showerhead with a baffle plate including baffle orifices according to the present disclosure;

FIGS. 4D and 4E are plan views of examples of faceplates including different arrangements of posts according to the present disclosure;

FIGS. 5-9 are a plan views of examples of baffle plates arranged above a faceplate according to some embodiments of the present disclosure;

FIG. 10 is a side cross-sectional view of an example of a showerhead assembly including back side gas delivered along a back side of the showerhead of FIG. 4A;

FIG. 11 is a bottom view of an example of a showerhead faceplate including inner and outer zones including gas through holes according to some embodiments of the present disclosure;

FIG. 12 is a graph illustrating an example of film thickness as a function of substrate diameter deposited on a substrate using the showerhead of FIG. 4A;

FIGS. 13 and 14 are flowcharts of examples of methods for depositing film using the showerhead according to the present disclosure;

FIG. 15 is a side cross-sectional view of an example of a showerhead assembly including a backside gas system according to the present disclosure;

FIG. 16 is a partial side, cross-sectional, perspective view of an example of a portion of a showerhead assembly including a backside gas system according to some embodiments of the present disclosure; and

FIG. 17 is a perspective view of an example of an annular support according to some embodiments of the present disclosure.

In the drawings, reference numbers may be reused to identify similar and/or identical elements.

### DETAILED DESCRIPTION

In deposition processes such as chemical vapor deposition (CVD), atomic layer deposition (ALD) or other deposition processes, a showerhead may be used to deliver and distribute process gases such as precursor, inert gases and/or purge gases from a gas delivery system to the processing chamber. The showerhead typically includes an upper portion extending downwardly in the processing chamber and a lower portion connected to the upper portion. The gas delivery system is connected to a gas channel extending in a first direction through the upper portion. The gas channel delivers the process gases through the upper portion to a gas plenum of the showerhead. A faceplate of the lower portion includes a plurality of gas through holes. Process gases from the gas plenum flow through the faceplate and onto the substrate arranged below the faceplate.

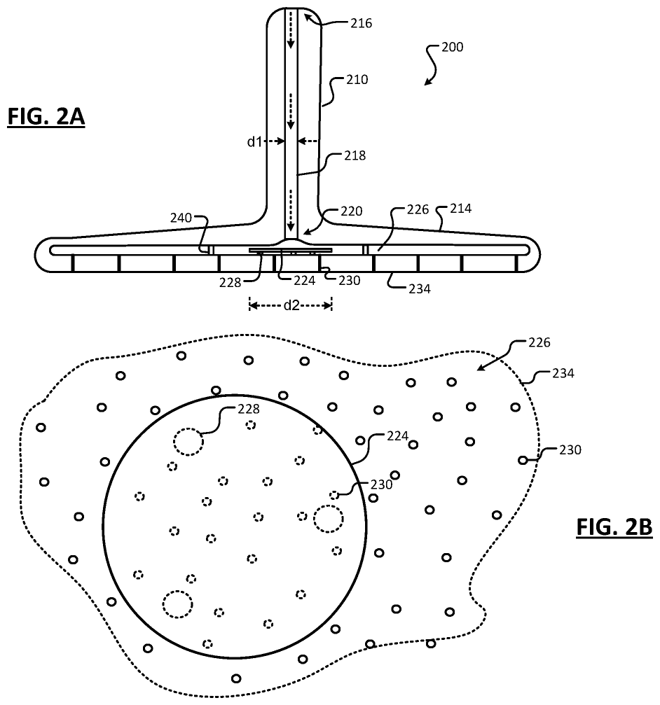

In some instances, jetting may occur when the process gases from the upper portion pass through vertically aligned gas through holes that are located directly below the outlet of the gas channel. Gas jetting may create defects such as high spots on the substrate. In some commercialized showerheads, a solid baffle plate is arranged below the gas channel to eliminate jetting and redirect the process gases, see for example FIGS. 2A and 2B. However, the solid baffle plate causes shadowing to occur on the substrate. Shadowing refers to center low thickness in regions below the baffle plate caused by localized reduced gas flow.

FIG. 2A illustrates a side cross-sectional view of a commercialized showerhead with a solid baffle plate arranged within. In FIG. 2A, the showerhead 200 includes an upper portion 210 extending downwardly from an upper surface of the processing chamber and a lower portion 214 connected to the upper portion 210. A gas plenum 226 is defined between the upper portion 210 and the lower portion 212. The lower portion 214 includes a faceplate 234. The upper portion 210 includes a gas channel 218 with an inlet 216 in communication with the gas delivery system and an outlet 220 connected to the gas plenum 226.

Gas flowing through the gas channel 218 impinges upon a solid baffle plate 224 attached to the faceplate 234 in the gas plenum 226. The solid baffle plate 224 reduces jetting in substrate locations arranged beneath the baffle plate 224 since none of the gas has a direct vertical path from the gas channel to an aligned gas through hole. With this arrangement, however, less gas flows through the gas through holes located directly below the baffle plate 224. Since less process gas is delivered, less deposition occurs below the baffle plate 224.

In FIG. 2A, the gas channel 218 has an inner diameter having a width d1 in a horizontal direction (transverse to a direction of the gas flowing through the gas channel 218). The solid baffle plate 224 has a width d2 in the horizontal direction. To ensure that the gas momentum changes from a vertical direction to a horizontal direction, the width d2 of the solid baffle plate 224 is typically significantly wider than the width d1 of the inner diameter of the gas channel 218. Typically, d2>=4*d1.

Further, in FIG. 2A, posts 240 are positioned close to the outer edge of the solid baffle plate 224. Some commercialized showerheads may have excessive number of posts 240 (for example more than 50) that connect the faceplate 234 to the upper portion 210. Excessive number of posts 240 may hinder the placement of gas through hole on the faceplate and thus lead to uneven deposition layers.

In FIG. 2B, the solid baffle plate 224 in FIG. 2A is shown in further detail. The solid baffle plate 224 is supported on three posts 228 above a surface of the faceplate 234. The gas flow is diverted in a lateral direction by the solid baffle plate 224, fills the gas plenum 226, and passes through the gas through holes 230 in the faceplate 234 to expose the substrate. The solid baffle plate 224 causes less gas to pass through gas through holes positioned directly underneath the solid baffle plate 224 which causes non-uniform deposition thickness on the substrate.

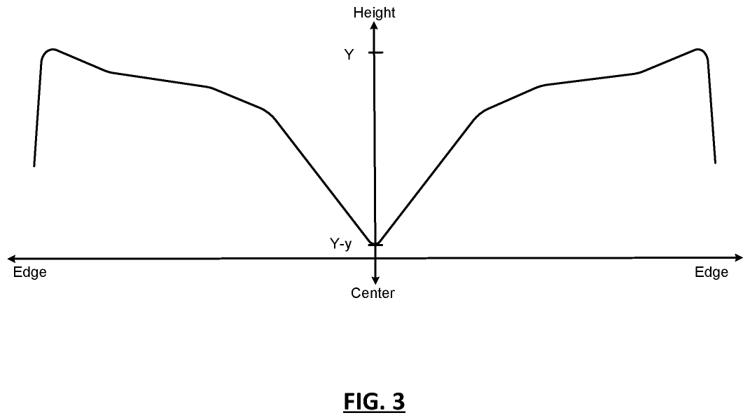

Referring now to FIG. 3, the showerhead shown in FIGS. 2A and 2B produces film having non-uniform thickness. After deposition, the film has a center low profile in areas below the baffle plate. In other words, the center is lower than the edges by a distance-y. This effect may be referred to as shadowing. Complete removal of the solid baffle plate 224 is not possible since jetting would occur in the absence of the solid baffle plate 224. Embodiments of the present disclosure describe new showerhead assemblies that improve the overall gas distribution uniformity.

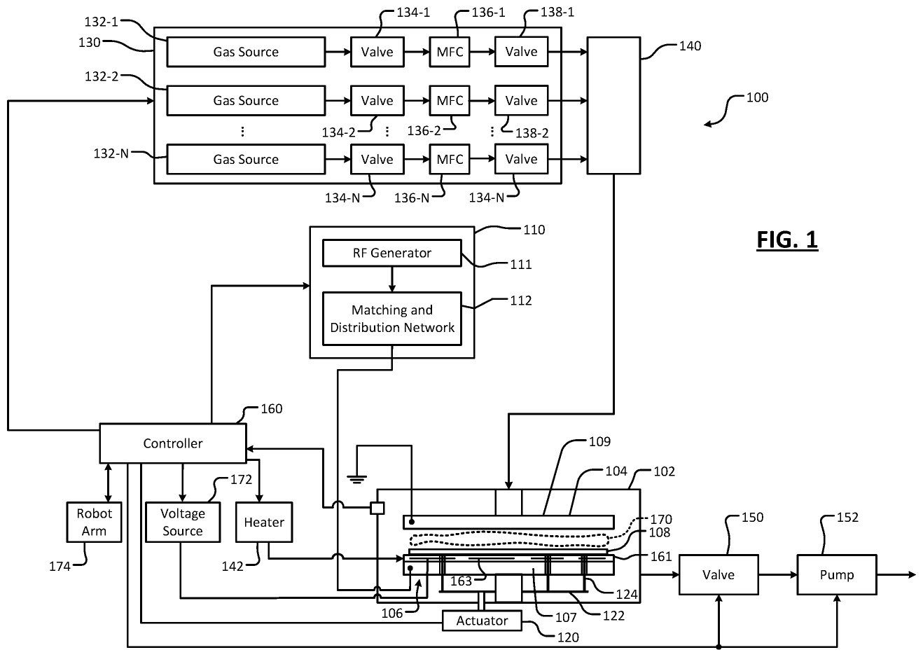

Referring now to FIG. 1, an example of a substrate processing system 100 for performing a substrate treatment is shown. In the example described below, the substrate processing system may perform thermal or plasma-enhanced chemical vapor deposition (CVD), thermal or plasma-enhanced atomic layer deposition (ALD), or other deposition process. In some embodiments, the substrate processing chamber deposits a dielectric film such as an oxide film, although other films may be deposited. However, the showerhead may also be used to distribute process gases for other types of substrate treatments either with or without plasma.

The substrate processing system 100 includes a processing chamber 102 that encloses other components of the substrate processing system 100 and contains the RF plasma (if used). The substrate processing system 100 includes an upper electrode 104 and an electrostatic chuck (ESC) 106. In some embodiments, the ESC 106 includes a ceramic top layer 161 bonded to a baseplate 107 acting as a lower electrode. During operation, a substrate 108 is arranged on the ESC 106 between the upper electrode 104 and the lower electrode. The ESC 106 includes electrodes 163 that electrostatically attract the substrate during deposition. The electrodes 163 can be monopolar electrodes or bipolar electrodes.

For example, the upper electrode 104 may include a showerhead 109 that introduces and distributes process gases. The showerhead 109 may include an upper portion including one end connected to a top surface of the processing chamber. A lower portion is generally cylindrical and extends radially outwardly from an opposite end of the upper portion at a location that is spaced from the top surface of the processing chamber. A substrate-facing surface or faceplate of the base portion of the showerhead includes a plurality of gas through holes through which process gas or purge gas flows.

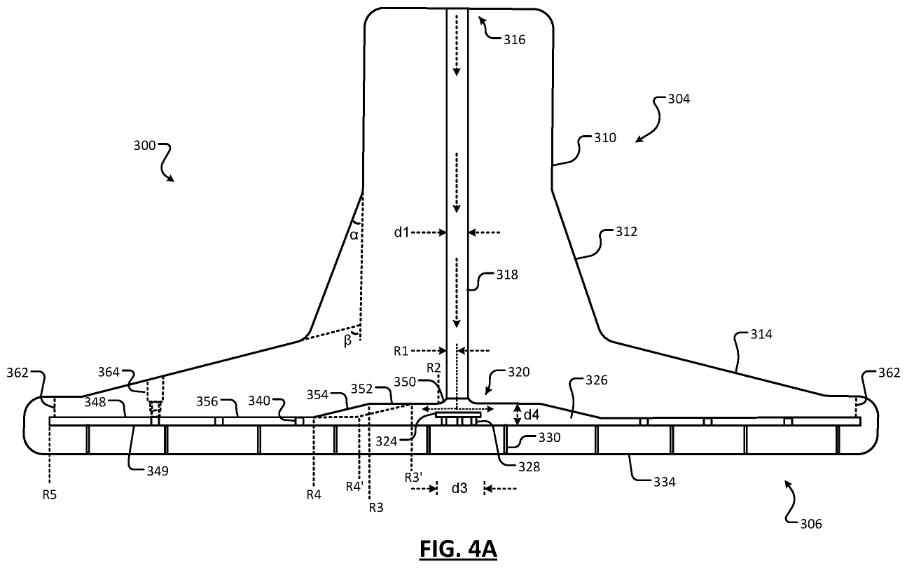

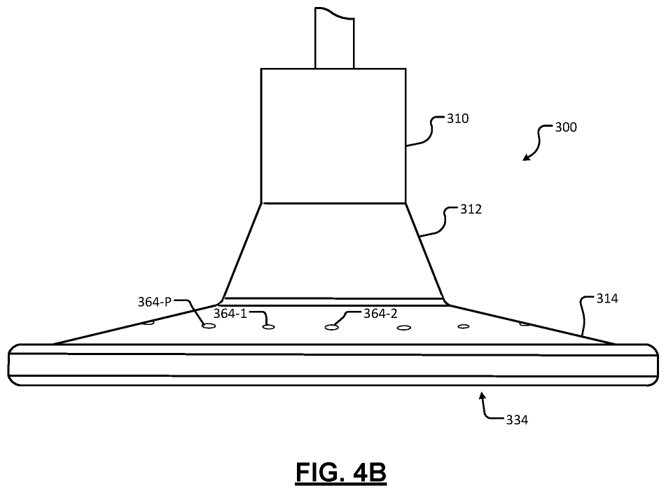

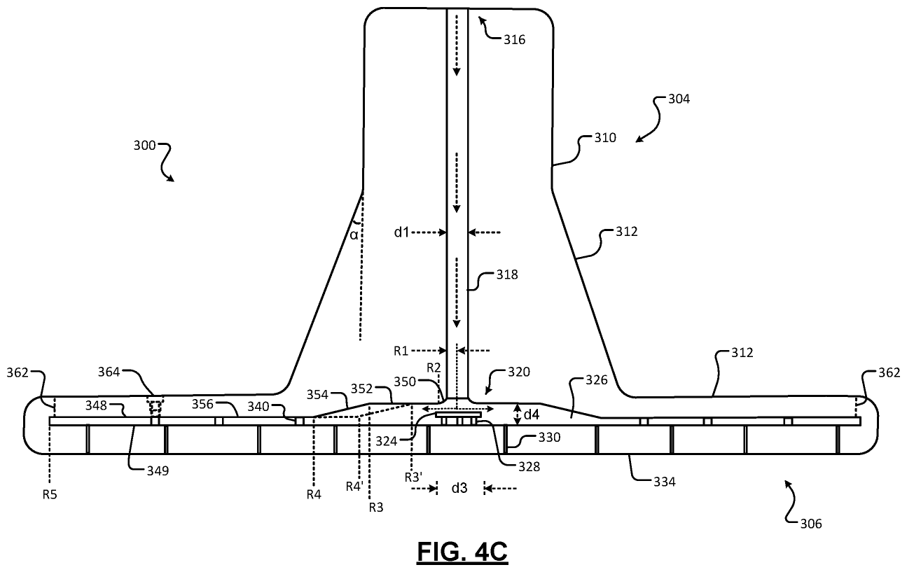

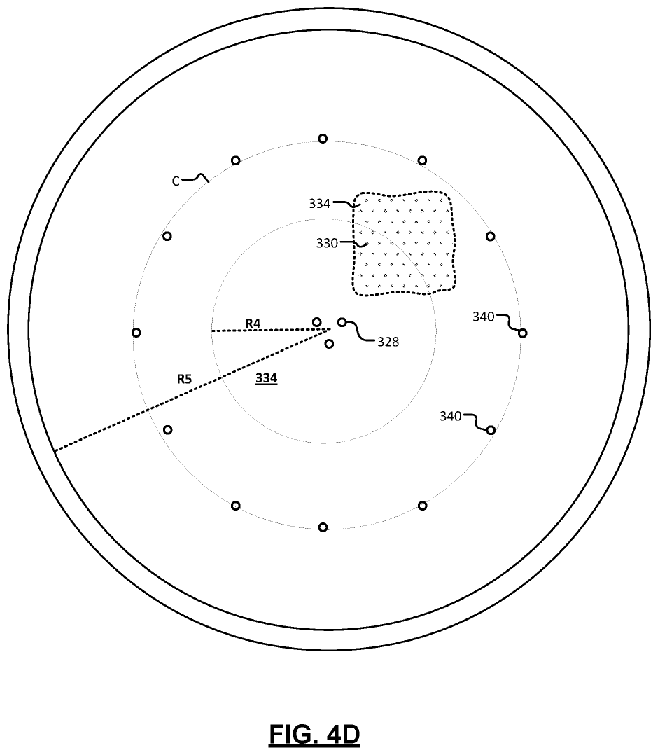

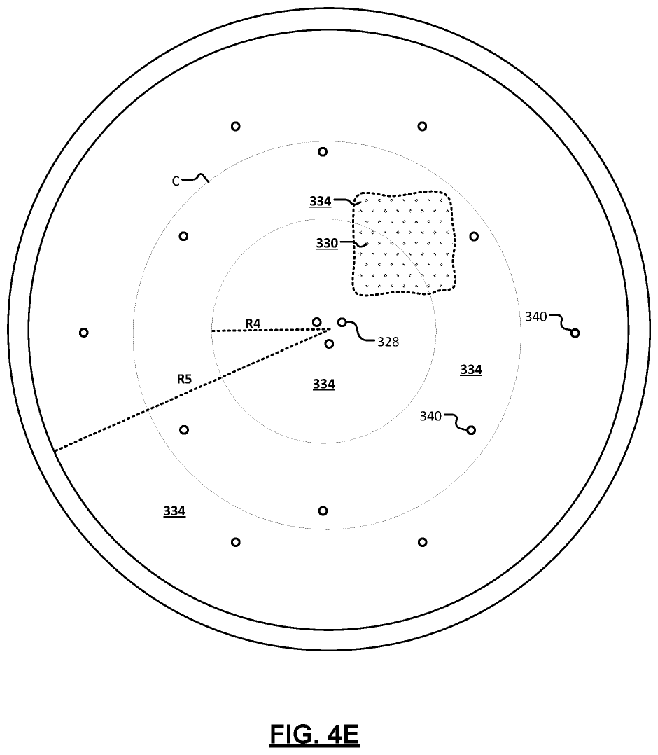

As will be described further below in conjunction with FIGS. 4A-9, the showerhead according to the present disclosure includes a porous baffle plate including baffle orifices. The baffle plate is arranged in the gas plenum between the gas channel and the faceplate. The baffle orifices allow additional gas flow through the gas through holes located below the baffle plate.

If plasma is used, an RF generating system 110 generates and outputs RF power at one or more frequencies and/or power levels to one of the upper electrode 104 and the lower electrode. The other one of the upper electrode 104 and the lower electrode may be DC grounded, AC grounded or floating. For example, the RF generating system 110 may include an RF generator 111 that generates the RF power that is fed by a matching and distribution network 112 to the lower electrode and the upper electrode 104 is grounded (or vice versa). An actuator 120 and a lift pin assembly 122 including P lift pins 124 (where P is an integer greater than 2) may be used during loading and unloading of the substrate from the chamber.

A gas delivery system 130 includes one or more gas sources 132-1, 132-2, . . . , and 132-N (collectively gas sources 132), where N is an integer greater than zero. The gas sources 132 supply one or more process gases such as deposition precursors, purge gas, etch gas, etc. In some embodiments, vaporized precursors may also be used (not shown). The gas sources 132 are connected by valves 134-1, 134-2, . . . , and 134-N (collectively valves 134), mass flow controllers 136-1, 136-2, . . . , and 136-N (collectively mass flow controllers 136), and valves 138-1, 138-2, . . . , and 138-N (collectively valves 138) to a manifold 140. An output of the manifold 140 is fed by the gas delivery system 130 to the processing chamber 102. For example, the output of the manifold 140 is fed to the showerhead 109.

A heater controller 142 may be connected to resistive heaters arranged in the ESC 106. The heater controller 142 may be used to control a temperature of the ESC 106 and the substrate 108. In addition, the ESC 106 may include internal channels (not shown) to flow a fluid from a fluid source (not shown) to provide further control of the pedestal and substrate temperatures. A valve 150 and pump 152 may be used to evacuate reactants from the processing chamber 102 and/or to control pressure in the processing chamber. A controller 160 may be used to control the various components of the substrate processing system 100 described herein.

As will be described further below, the controller 160 causes a robot arm 174 to load the substrate 108 onto the ESC 106. The controller 160 communicates with the gas delivery system 130 to control supply of process, purge and/or inert gases. The controller communicates with the valve 150 and pump 152 to control pressure within the processing chamber and/or evacuation of reactants. The controller 160 also causes a voltage source 172 to output voltage to the electrodes to clamp and unclamp the substrate.

Referring now to FIGS. 4A-4E, a showerhead 300 according to some embodiments of the present disclosure is shown in further detail. In FIGS. 4A and 4B, the showerhead 300 includes an upper portion 304 and a lower portion 306. The upper portion 304 includes an upper portion 310 extending downwardly from an upper surface of the processing chamber, a first cone-shaped portion 312 extending outwardly from the upper portion 310. A second cone-shaped portion 314 extends outwardly from the first cone-shaped portion 312.

A gas channel 318 extends vertically through the upper portion 304 and includes an inlet 316 in communication with the gas delivery system and an outlet 320 delivering process gas to a gas plenum 326 defined by facing surfaces of the upper portion 304 and the lower portion 306. In some embodiments, the gas plenum 326 defines a generally cylindrical volume with a cone-shaped portion on a radially inner portion of the top surface thereof (to provide clearance for gas to flow around the baffle plate described below).

The first cone-shaped portion 312 forms a first acute angle α relative to side surfaces of the upper portion 310. The second cone-shaped portion 314 forms a second acute angle β relative to side surfaces of the upper portion 310. In some embodiments, the first acute angle α is less than the second acute angle β. In some embodiments, the first acute angle α is in a range from 15° to 50. In other embodiments, the first acute angle α is in a range from 15° to 25°, although other values can be used. In some embodiments, the second acute angle β is in a range from 60° to 85°. In other embodiments, the second acute angle β is in a range from 70° to 80°, although other values can be used. The relatively smooth transition of side surfaces of the upper portion allows less turbulent backside gas flow, which improves the effectiveness of the gas curtain and reduces parasitic plasma (if used).

In FIG. 4C, another example embodiment of the showerhead is shown. The second cone-shaped portion 314 is omitted and the first cone-shaped portion 312 extends downwardly and then transitions to a planar portion 315 that extends in a first plane spaced above and parallel to a plane including the faceplate 334.

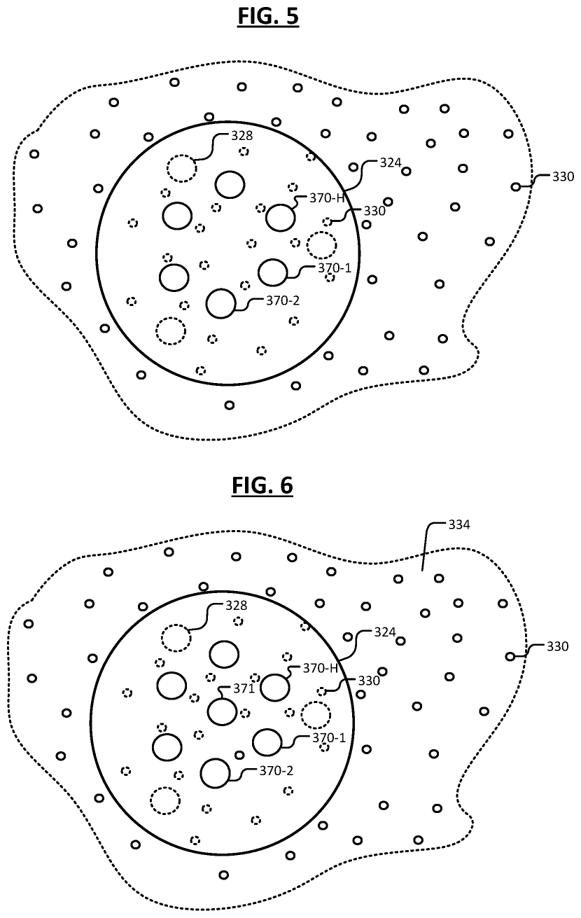

Gas flowing through the gas channel 318 impinges upon a baffle plate 324 including a plurality of baffle orifices (examples of which are shown and described in FIGS. 5-9 below). The baffle plate 324 has a flat cylindrical shape and is oriented in a horizontal direction below the gas channel 318. A horizontal surface of the baffle plate 324 causes a portion of the gas from the gas channel 318 to change momentum from a vertical direction to a lateral direction and to fill radially outer portions of the gas plenum 326. As will be described further below, the plurality of baffle orifices in the baffle plate 324 allows some of the process gas to flow through the baffle plate 324 (and gas through holes below the baffle plate 324) to reduce or prevent shadowing on the substrate.

The gas from the gas channel 318 flows into the gas plenum 326 and through gas through holes 330 in a faceplate 334. The baffle plate 324 is mounted on B posts 328 above a surface of the gas plenum 326 adjacent to the faceplate 334, where B is an integer greater than one. In some embodiments, B=3, although additional posts may be used, such as B=4 or B=5.

In this example, the inner diameter of the gas channel 318 has the width d1 in a horizontal direction that is transverse to a vertical direction of gas flowing through the gas channel 318. The baffle plate 324 has a width d3 in the horizontal direction. The width d3 of the baffle plate 324 is typically wider than the width d1 of the gas channel 318 to ensure that the vertical momentum of the process gas changes to a horizontal direction. Through testing, it was determined that the shadowing effect was reduced more significantly when the width d3 of the baffle plate 324 is wider than the width d1 but narrower than the width d2 shown in FIG. 2A. In some embodiments, the width d3 is in a range from 1.25*d1 to 3*d1, although other widths may be used. In some embodiments, the width d3 is in a range from 1.75*d1 to 2.5*d1, although other widths may be used.

At a first radius R1, the outlet 320 transitions to a rounded portion 350 ending at a second radius R2. The rounded portion 350 helps reduce gas flow turbulence. At the second radius R2, the upper surface 348 transitions at an acute angle to a first horizontal portion 352 until a third radius R3 (greater than R2). At the third radius R3, the upper surface 348 transitions to a tapered portion 354 that extends to a fourth radius R4 (greater than R3). The first horizontal portion 352 and the tapered portion 354 provide clearance for gas to flow smoothly around the baffle plate 324.

In some embodiments, the acute angle is in a range from 8° to 20°. In some embodiments, the acute angle is in a range from 10° to 14°, although other angles can be used. At the fourth radius R4, the upper surface transitions to a second horizontal portion 356 that is parallel to a lower surface 349 of the gas plenum 326 and extends to a fifth radius R5. The first horizontal portion 352 and the tapered portion 354 define an enlarged center cavity in a region around the baffle plate 324 to increase gas conductance and ensure uniform gas flow.

The length, angle, and radial position of the first horizontal portion 352 and the tapered portion 354 are selected to ensure uniform gas flow as the momentum of the gas flow changes from the vertical direction to the horizontal direction. The rounded portion 350 and the tapered portion 354 are configured to increase gas conductance in the gas plenum and to decrease high or low pressure locations. As can be appreciated, the location of the tapered portion 354 can be moved radially inwardly as shown by dotted lines R3′ and R4′.

In some embodiments, R3 is in a range from 0.7*d3 to 2.5*d3, although other values can be used. In some embodiments, R3 is in a range from d3 to 2.0*d3, although other values can be used. If R3 is too small, the process gas flow can be restricted (causing localized increased pressure) and variations in process gas flow though the gas through holes 330 may occur. If R3 is too large, the process gas may have lower local pressure and variations in process gas flowing though the gas through holes 330 in this location may occur. Localized variations in gas delivery due to higher or lower pressure regions may cause shadowing effects or film non-uniformity.

In some embodiments, the showerhead is assembled by attaching heads of P posts 340 to an inner surface of the faceplate 334 of the lower portion 306, where P is an integer greater than one. Then, an upper portion 304 of the showerhead is attached to the lower portion 306. A radial edge 362 is attached to a corresponding edge of the faceplate 334. Shafts of the P posts 340 are inserted into and attached to the upper portion 304 through corresponding access holes 364 (one access hole is shown) that pass through the second cone-shaped portion 314. In some embodiments, the P posts 340 are welded or swaged to the faceplate 334 and/or in the access holes 364 of the upper portion 304.

The P posts 340 connect the upper portion 304 to the faceplate to help maintain spacing between the upper surface 348 and the faceplate 334 during significant temperature changes that occur during processing. In other words, the P posts 340 resist movement of the faceplate 334 due to expansion/contraction caused by heating and cooling that may cause defects or non-uniformity. In some embodiments, the number of posts P is set in a range from 8 to 24. Without being limited to a particular theory, fewer than 8 posts do not typically prevent movement of the faceplate sufficiently while more than 24 posts do not provide sufficient performance improvement to warrant machining and/or material costs.

As shown in FIG. 4D, in some embodiments, P=12, the P posts 340 are arranged in a circle C having a radius between R4 and R5, and the P posts 340 are equally spaced around the circumference of the circle. Some angular adjustment of the spacing of the P posts 340 away from 360/P and the circle C may be required to placing the posts over the gas through holes 330 through the faceplate. In some embodiments, P may be equal to 14, 16, 18, 20, or 22. In some commercialized showerheads, a significantly higher number of posts were used, which increased the cost to manufacture the showerhead. Too many posts also reduce locations where the gas through holes can be arranged on the faceplate. In some embodiments, the P posts 340 are arranged in two or more circles having predetermined radii between R4 and R5.

In FIG. 4E, in other embodiments, the P posts are arranged in non-circular patterns between R4 and R5. In some embodiments, the P posts 340 are arranged between 25% and 75% of the distance between R4 and R5.

In some embodiments, the P posts 340 have an inverted “T”-shaped cross section and include a head and a shaft. The head has a larger diameter than the shaft. A top surface of the head of the P posts 340 is attached to the surface 349 the faceplate. The shafts of the P posts 340 are inserted into and attached to inner surfaces of the access holes 364 in the second cone-shaped portion 314.

In some embodiments, a ratio of the height of a head of the P posts 340 to the diameter of the head of the P posts 340 is in a range from 0.5 to 1.0. In other embodiments, a ratio of the height of a head of the P posts 340 to the diameter of the head of the P posts 340 is in a range from 0.6 to 0.8.

In some embodiments, a ratio of the height of the P posts 340 (including the head and the shaft) to the diameter of the head of the P posts 340 is in a range from 0.2 to 0.5. In other embodiments, a ratio of the overall height of the P posts 340 (including the head and the shaft) to the diameter of the head of the P posts 340 is in a range from 0.25 to 0.35. In some embodiments, a ratio of a diameter of the shaft to the diameter of the head is in a range from 0.70 to 0.95. In other embodiments, a ratio of a diameter of the shaft to the diameter of the head is in a range from 0.80 to 0.90.

Referring back to FIG. 4A, a vertical distance d4 of the gas plenum 326 is defined between the surface 349 of the faceplate 334 and the first horizontal portion 352. In some embodiments, the baffle plate 324 is vertically centered between 0.25*d4 and 0.75*d4. In some embodiments, a plane defined by the second horizontal portion 356 passes through the baffle plate 324. The vertical location of the baffle plate 324 in the gas plenum 326 is selected to ensure sufficient gas flow laterally (and then through the gas through holes 330 arranged radially outside of the baffle plate 324) and vertically through the baffle orifices of the baffle plate 324 (and then through the gas through holes 330 underlying the baffle plate 324) to allow uniform gas flow.

In FIG. 5-9, various examples of baffle orifices in the baffle plate 324 are shown in further detail. In FIG. 5, the baffle plate 324 is supported above a surface of the faceplate 334 on the B posts 328. While B=3 posts are shown, additional posts can be used. The baffle plate 324 includes a plurality of baffle orifices 370-1, 370-2, . . . , and 370-H (collectively baffle orifices 370), where H is an integer greater than one. While most of the gas flow is diverted laterally by the baffle plate 324 and eventually passes through the gas through holes 330 in the faceplate 334, at least some of the gas flow travels vertically through the baffle orifices 370 in the baffle plate 324 and then at least partially laterally, and then vertically through the gas through holes 330 located below the baffle plate 324.

In some embodiments, the baffle orifices 370 are arranged symmetrically relative to a center of the baffle plate 324 to ensure uniform gas flow relative to the center of the substrate. In the example shown in FIG. 5, H=6 and the baffle orifices 370 are arranged symmetrically in a circular pattern, although additional or fewer gas through holes can be used. In some embodiments, the diameter of the baffle orifices 370 is in a range of 1.2 to 6 times larger than the gas through holes 330 in the faceplate 334, although other diameters can be used. In some embodiments, the diameter of the baffle orifices 370 are in a range of 1.5 to 3 times larger than the gas through holes 330 in the faceplate 334, although other diameters can be used.

In some embodiments, the baffle plate 324 is clocked or rotationally oriented such that the baffle orifices 370 are misaligned with the gas through holes 330 in the faceplate 334 that are located vertically below the baffle orifices 370. Since the baffle orifices are misaligned, the gas flows vertically through the baffle orifices, impinges on the faceplate and is diverted horizontally, and then the gas passes vertically through the gas through holes 330. In FIG. 6, an additional baffle orifice 371 is arranged in the center of the baffle plate 324. Arrangement of the baffle orifice 371 in the center of the baffle plate 324 maintains symmetry of the baffle orifices to promote uniform gas flow. Symmetry of the baffle orifices in the baffle plate 324 tends to equalize gas flowing the gas through holes 330 in the faceplate 334 that are located vertically below the baffle orifices 370.

In some embodiments, regardless of the total number of baffle orifices, baffle plate 324 has about 2% to 10% surface area covered by baffle orifices (excluding holes for posts 328). In some embodiments, regardless of the total number of baffle orifices, baffle plate 324 has about 4% to 8% surface area covered by baffle orifices (excluding holes for posts 328). The surface area is defined by the surface of the baffle plate 324 facing the gas channel 318.

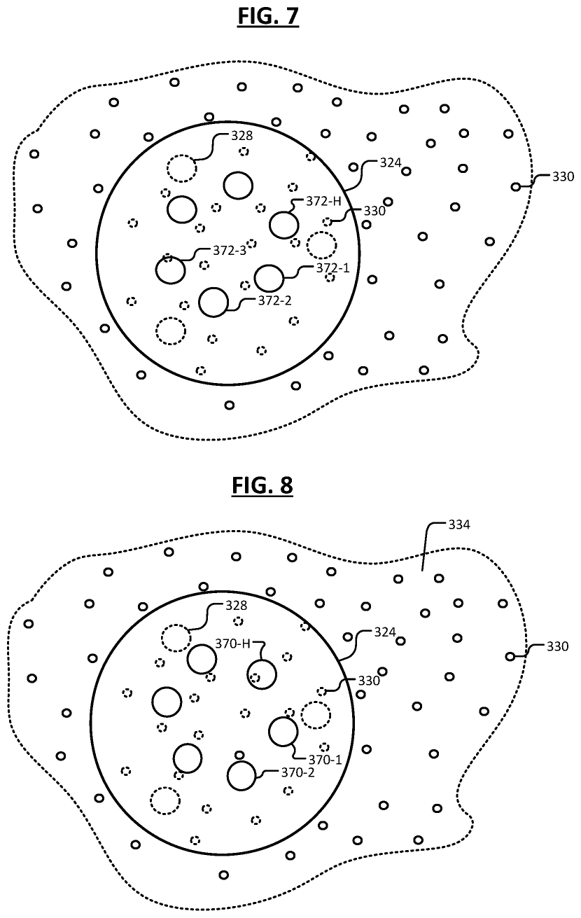

In FIG. 7, the baffle plate 324 includes baffle orifices 372-1, 372-2, 372-3, . . . , 372-H. At least one of the baffle orifices 372-1, 372-2, . . . , and 372-H (e.g., 372-3 in FIG. 7) at least partially overlaps at least one of the gas through holes 330 in the faceplate that is located vertically below. As can be appreciated, partial overlap may be used to strategically supply additional process gas in certain locations via the at least one of the gas through holes 330 to allow fine tuning of process gas delivery. For example, partial overlap can be used where localized shadowing or low spots occur on the substrates despite the use of the baffle plate with baffle orifices.

In FIG. 8, at least one of the baffle orifices 370-1, 370-2, . . . , and 370-H (e.g., 370-H in FIG. 8) fully overlaps at least one of the gas through holes 330 in the faceplate 334 that is located vertically below the baffle plate 324 while the remaining ones of the baffle orifices are misaligned. As can be appreciated, complete overlap may be used to strategically supply additional process gas at certain locations via the at least one of the gas through holes 330 to allow fine tuning of process gas delivery.

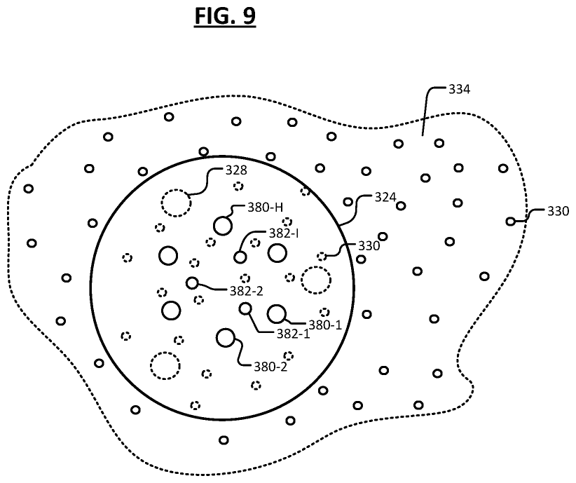

As can be appreciated, while specific hole patterns and numbers of baffle orifices are shown, other hole patterns and numbers of baffle orifices can be used to further fine tune gas delivery. For example, a larger number of baffle orifices each having smaller and/or larger diameters can be used to further adjust gas flow to prevent shadowing. For example in FIG. 9, baffle orifices 380-1, 380-2, . . . , and 380-H and baffle orifices 382-1, 382-2, . . . , and 382-I are shown. In this example, the baffle orifices 380-1, 380-2, . . . , and 380-H have a larger diameter than the baffle orifices 382-1, 382-2, . . . , and 382-1. While the baffle orifices are arranged in a spaced configuration in a first circular pattern in FIGS. 5-8, the baffle orifices 382-1, 382-2, . . . , and 382-I are arranged in a first circular pattern within a second circular pattern including the baffle orifices 380-1, 380-2, . . . , and 380-H. In other embodiments, the diameters of baffle orifices in a given circular pattern can be different to adjust localized gas delivery. While circular baffle orifices are depicted in FIGS. 5-9, in some embodiments, the baffle orifices can be in different shapes such as oval, rectangle, triangle, square, or a combination thereof.

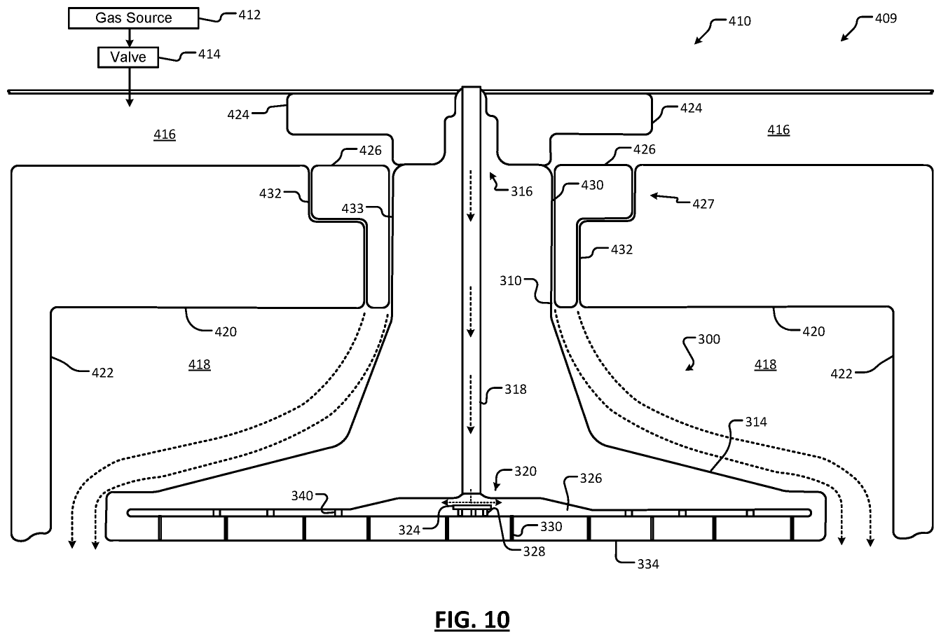

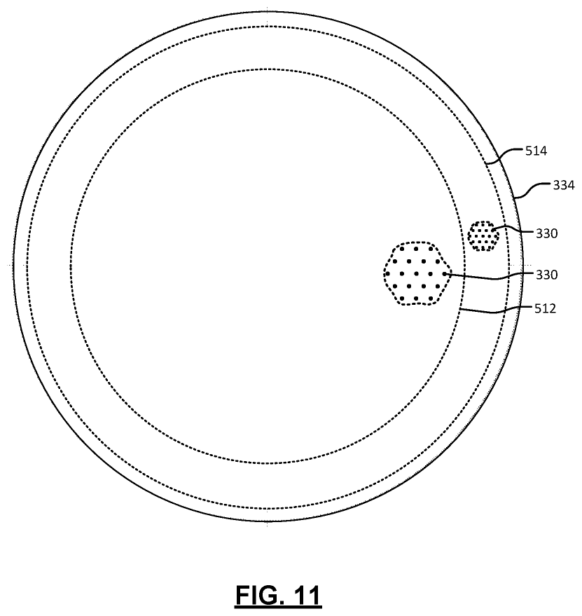

Referring to FIG. 10, additional improvements in non-uniformity can be achieved using a showerhead assembly 409 including a back side gas system 410 to supply back side gas along a back side of the showerhead. In some embodiments, the back side gas system 410 includes a gas source 412 and a valve 414 to supply back side gas to a cavity 416. The showerhead is mounted inside a processing volume 418 of a processing chamber including an upper surface 420 and sidewalls 422. Annular supports 424 and 426 are used to mount the showerhead in the processing chamber. The annular support 426 is arranged below the annular support 424. The upper surface 420 of the processing chamber includes an opening 427 to receive the annular support 426. Annular gaps 432 and 433 are defined between the annular support 426 and the opening in the upper surface 420 and between the annular support 426 and the upper portion 310, respectively. The annular gap 432 is arranged at an outer diameter of the annular support 426 and the annular gap 433 is arranged at an inner diameter of the annular support 426.

The back side gas from the gas source 412 flows through the annular gaps 432 and 433 and across the side surfaces defined by the upper portion 310, the first cone-shaped portion 312 and the second cone-shaped portion 314. In some embodiments, the gas is an inert gas such as argon (Ar). In other embodiments, a gas such as molecular oxygen (O₂) is used. The back side gas flow reduces parasitic plasma above the showerhead and improves uniformity of process gas flow from the showerhead at edges of the substrate. The back side gas flow also provides a gas curtain around a radially outer edge of the showerhead to contain and concentrate the process gas supplied by the showerhead to a radius around a radially outer edge of the substrate.

Referring now to FIG. 11, a substrate-facing surface of the faceplate 334 is shown to include gas through hole patterns defining an inner zone 512 and an outer zone 514. The inner zone 512 and the outer zone 514 include the gas through holes 330 with different patterns and/or spacing. In some embodiments, the inner zone 512 extends to a first radius and the outer zone 514 extends from the first radius to a second radius. In some embodiments, a density of the gas through holes 330 is greater in the outer zone 514 as compared to a density of the gas through holes 330 in the inner zone 512 as shown.

In this example, the patterns in the inner zone 512 and the outer zone 514 have the same shape but the gas through holes are arranged closer together. In other embodiments, both the pattern and density are different. In still other embodiments, the hole patterns have the same size but the diameter of the gas through holes in the inner zone 512 are smaller than the outer zone 514. In some embodiments, the first radius of the inner zone 512 is greater than or equal to 0.7 times the second radius of the outer zone 514. In some embodiments, the first radius is greater than or equal to 0.8 times the second radius.

In some applications using a faceplate with a single zone with uniform density of gas through holes, gas flowing through the gas through holes 330 in radially outer regions of the faceplate 334 may be reduced causing less film deposition in the radially outer portions of the substrate. Increasing the density of the gas through holes 330 in the outer zone 514 relative to the inner zone 512 increases flow of process gas supplied in the outer zone 514, which reduces non-uniformity.

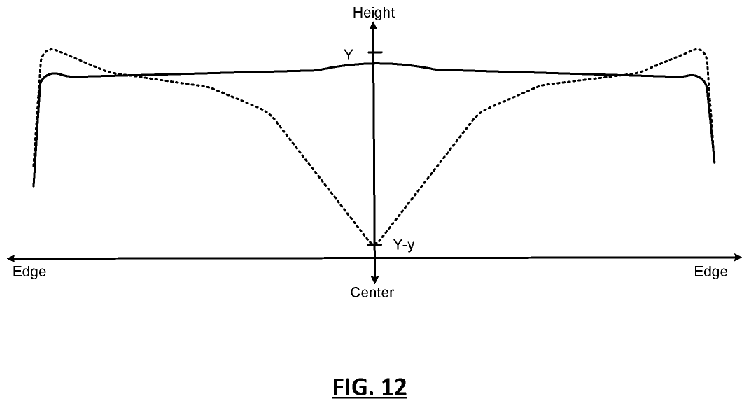

Referring now to FIG. 12, the showerhead assembly (shown in FIG. 4A) including one or more of the features described above delivers gas to the substrate more uniformly. As a result, the processing chamber with the showerhead produces film having more uniform thickness in the center and at the edges. In other words, both the center and edge of the film deposited on the substrate are closer to the height Y (rather than the edge at height Y and the center at height (Y-y) as shown in FIG. 3). Without being limited to any particular theory, the baffle plates in FIGS. 5-9, the placement of the baffle plate, the center cavity space, the backside gas, the reduced number and specific placement of support posts, and other features described herein allow more uniform delivery of process gas to the center of the substrate while still protecting the center portion of the substrate from the adverse effects of jetting. This, in turn, significantly reduces non-uniformity in the thickness of the substrate at the center.

As was described above, the showerhead including the baffle plate with baffle orifices can be used to deposit film. For example during chemical vapor deposition (CVD) or plasma-enhanced CVD (PECVD), the substrate is exposed to one or more precursor gases and heat, plasma or a reactant may be used to cause a chemical reaction that deposits film onto the substrate. Typically, the thickness of the film can be controlled at least partially by the duration of the exposure to the precursor and reactant gases, gas flow rates, plasma power, substrate temperature and/or chamber pressure.

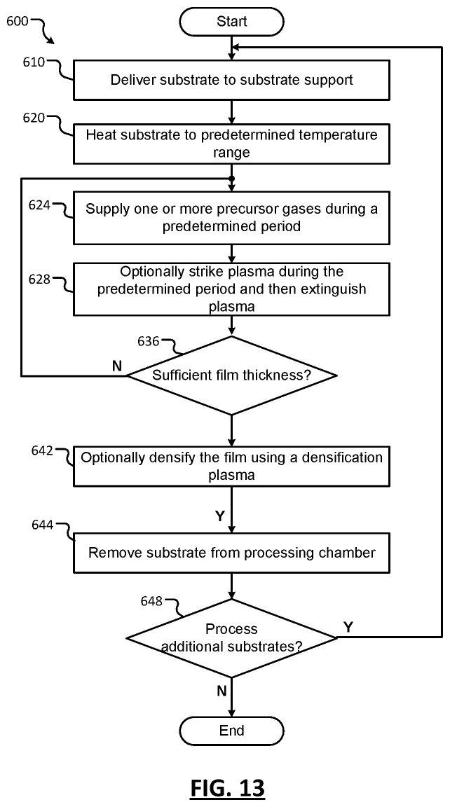

In FIG. 13, examples of a method 600 for depositing film using CVD or PECVD using a showerhead or showerhead assembly including a baffle plate with baffle orifices and other features according to the present disclosure is shown. For example, the CVD or PECVD process may be used to deposit a dielectric film such as silicon oxide (SiₓO_{y} where x and y are integers greater than or equal to one), although other types of film may be deposited.

At 610, a substrate is delivered onto a substrate support in the processing chamber. At 620, the processing chamber pressure is set to a predetermined pressure range and the substrate is heated to a predetermined temperature range. At 624, one or more precursor gases are supplied to the processing chamber via the showerhead with the baffle plate including the baffle orifices for a predetermined period. In some embodiments, the back side gas system supplies back side gas during deposition of film to prevent backside parasitic plasma and/or to provide a gas curtain.

Plasma may optionally be struck in the processing chamber to promote chemical reactions at 628. The plasma power can be supplied continuously or switched between two or more RF power levels at predetermined sub-intervals during the predetermined period. After a predetermined period, the plasma is extinguished (if used). Gas purging and/or evacuation of the processing chamber may be performed as needed.

The method 600 may perform additional CVD or PECVD cycles to increase the thickness of the film deposited on the substrate as determined at 636. For example, deposition can be stopped periodically to allow densification or passivation steps to be performed. In some embodiments, the densification step performed by supplying a densification gas and striking plasma for a predetermined period. In some embodiments, the densification gas includes an inert gas such as helium, a mixture of helium and molecular oxygen and/or gases or gas mixtures.

If 636 is false, the method returns to 624. When processing of the substrate has been completed, the substrate can optionally be exposed to densification plasma at 642. At 644, the substrate is removed from the processing chamber. At 648, the method processes additional substrates by returning to 610 or ends.

As was described above, the showerhead including the baffle plate with baffle orifices can be used to perform a plurality of atomic layer deposition (ALD) or plasma-enhanced ALD (PEALD) cycles. During one ALD or PEALD cycle, the substrate is exposed to a precursor gas for a first predetermined period during which the precursor adsorbs onto an exposed surface of the substrate in a self-limiting manner. In some embodiments, approximately a monolayer is adsorbed onto the surface of the substrate. After the first predetermined period, the processing chamber is purged or evacuated. Then, a reactant gas is supplied to the processing chamber for a second predetermined period. Heat and/or plasma may be used to cause a chemical reaction between the precursor adsorbed on the surface of the substrate and the reactant gas to create the film. After the second predetermined period, the processing chamber is purged or evacuated. Additional cycles are performed to increase the thickness of the film.

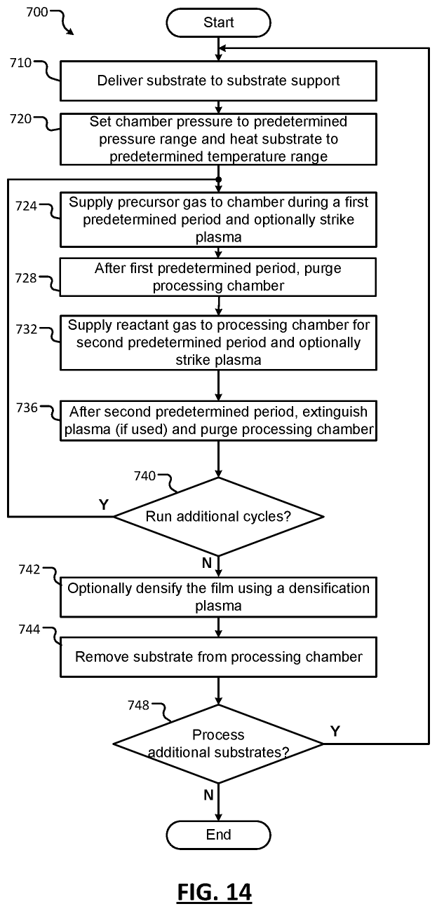

Referring now to FIG. 14, an example of a method 700 for depositing film using ALD or PEALD and a showerhead or showerhead assembly including a baffle plate with baffle orifices and other features described above is shown. For example, the ALD or PEALD process may be used to deposit a dielectric film such as silicon oxide (SiₓO_{y} where x and y are integers), although other types of film may be deposited.

At 710, a substrate is delivered onto a substrate support in the processing chamber. At 720, the processing chamber pressure is set to a predetermined pressure range and the substrate is heated to a predetermined temperature range. At 724, precursor gas is supplied using the showerhead (including the baffle plate with baffle orifices and/or other features described above) for a predetermined period to allow the precursor to adsorb onto the substrate in a self-limiting manner. In some embodiments, the predetermined period is in a range from about 0.1 seconds(s) to about 60 s, 0.2 s to about 6 s, or about 0.3 s to about 2 s. As used herein, about means +/−10%. In some embodiments, the back side gas system supplies back side gas during deposition.

At 728, after the predetermined period, purge gas is supplied to evacuate the processing chamber. At 732, a reactive gas is supplied to the processing chamber using the showerhead to cause a chemical reaction with the precursor on the surface of the substrate. Plasma may optionally be struck in the processing chamber to promote chemical reactions. At 736, after a predetermined period, the plasma is extinguished (if used) and purge gas is supplied to evacuate the processing chamber.

If additional ALD or PEALD cycles are to be performed on the substrate, the method returns to 724. When processing of the substrate has been completed, the substrate can optionally be exposed to a densification plasma at 742. At 744, the substrate is removed from the processing chamber at 744. At 748, the method processes additional substrates by returning to 710 or ends.

In some embodiments, the temperature of the substrate is set in a range from 100° C. to 800° C. during processing. In other embodiments, the temperature of the substrate is set in a range from 300° C. to 700° C. during processing. In still other embodiments, the temperature of the substrate is set in a range from 350° C. to 500° C. during processing. In some embodiments, the process pressure is in a range from about 0.1 Torr (T) to about 30 T. In some embodiments, the process pressure is in a range from about 1 T to about 10 T.

If RF plasma is used, plasma power can be supplied at one or more frequencies in a range from 10 W to 10 KW. The RF power source may include one or more power sources operating at one or more frequencies such as low-frequency and high-frequency power sources. The low frequency source can operate in a range from about 10 kHz to about 500 kHz. In other embodiments, the low-frequency power source can operate in a range from about 200 kHz to about 450 kHz (e.g., 430 kHz). The high-frequency source can operate in a frequency range from about 1.5 MHz to about 3 GHZ. For example only, the high frequency source can operate at about 1.8 MHz, 13.6 MHZ, 27 MHz, 40 MHz, 60 MHz or 2.54 GHz, although other frequencies may be used.

In some embodiments, the film comprises silicon oxide and the precursor comprises a silicon-containing precursor. In some embodiments, the silicon-containing precursor comprises a silane. In some embodiments, the silane includes an aminosilane. An aminosilane includes at least one nitrogen atom bonded to a silicon atom. The aminosilane may also include hydrogen, oxygen, halogen and/or carbon atoms. Examples of aminosilanes include bis(tert-butylamino) silane (BTBAS), N-(dimethylaminosilyl)-N-ethylethanamine (SAM-24); tris(dimethyamino) silane (3DMAS) and tetrakis(dimethylamino) silane (4DMAS).

In some embodiments, the reactant comprises an oxygen-containing reactant or an oxygen and hydrogen-containing reactant. In some embodiments, the oxygen-containing reactant or oxygen and hydrogen-containing reactant is selected from a group consisting of molecular oxygen (O₂), hydrogen peroxide (H₂O₂), ozone (O₃), molecular hydrogen (H₂), water (H₂O) or combinations thereof.

Additional examples of film that may be deposited using the showerhead described herein are shown and described in commonly-assigned “THERMAL ATOMIC LAYER DEPOSITION OF SILICON-CONTAINING FILMS”, PCT Publication No. WO 2021/025874, filed on Jul. 24, 2020; “CONFORMAL THERMAL CVD WITH CONTROLLER FILM PROPERTIES AND HIGH DEPOSITION RATE”, PCT Publication No. WO 2022/020528, filed on Jul. 21, 2021; and “REDUCING INTRALEVEL CAPACITANCE IN SEMICONDUCTOR DEVICES”, PCT Publication No. 2022/006010, filed on Jun. 28, 2021, which are all hereby incorporated herein by reference in their entirety.

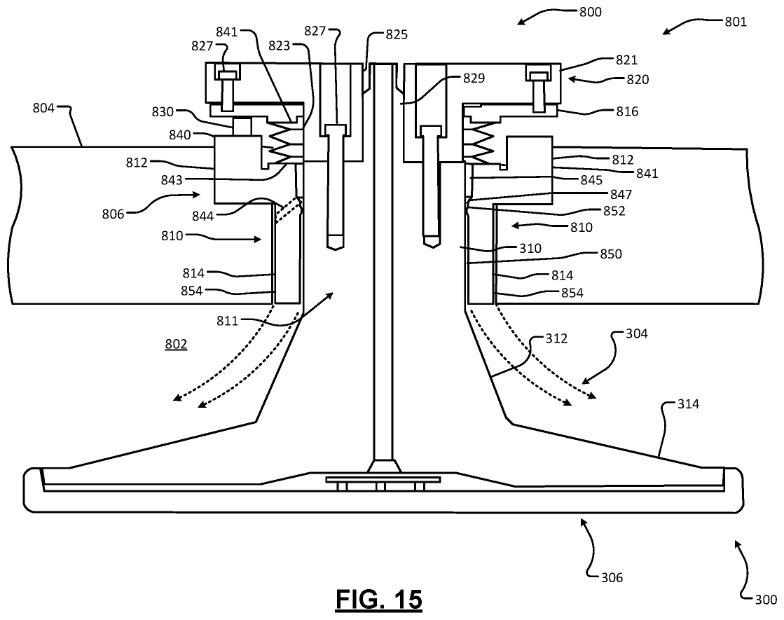

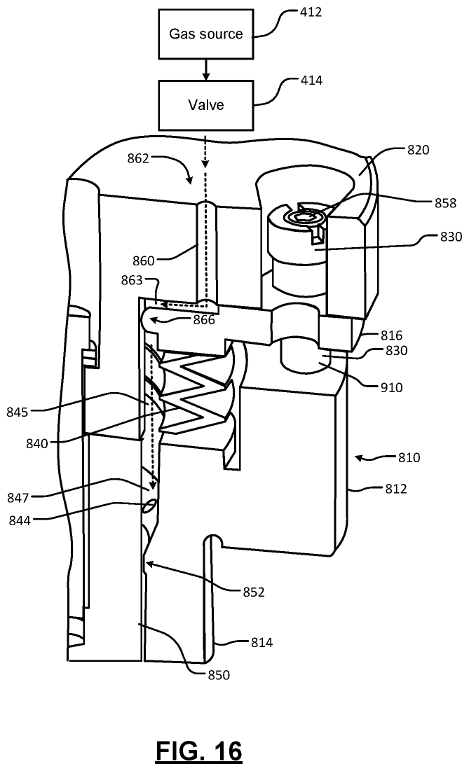

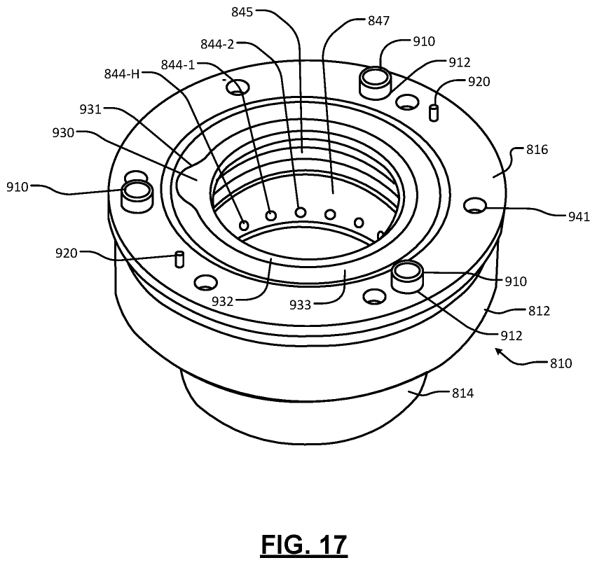

Referring now to FIGS. 15 and 16, additional improvements in non-uniformity can be achieved using showerhead assembly 800 including a showerhead 300 and a back side gas system 801. The showerhead 300 is mounted inside of a processing volume of the processing chamber. Back side gas is supplied to a back side volume 802 between the lower portion of the showerhead and an upper chamber surface to reduce parasitic plasma and/or provide a gas curtain. Process gas is supplied to the gas plenum and through the faceplate to deposit film on an exposed surface of the substrate. In some embodiments, the back side gas system 801 generates first and/or second annular gas flows along a radially outer surface of the showerhead.

When installing the showerhead in the enclosure of the processing chamber, the faceplate of the showerhead should be precisely located (e.g., spaced a predetermined distance from the substrate in a plane parallel to a plane including the substrate substate support) to avoid causing deposition non-uniformity. In other words, variations in the predetermined distance between the faceplate and the exposed surface of the substrate at different locations of the substrate cause deposition non-uniformity. Due to machining tolerance variations, the tilt of the showerhead may need to be precisely adjusted during setup or maintenance to align to the plane of the faceplate relative to the plane of the substrate support to prevent deposition non-uniformity.

When the showerhead is tilted relative to showerhead mounting structures during setup or maintenance, the first annular gas flow is reduced or restricted in certain radial locations. The showerhead assembly 800 in FIG. 15-17 delivers both first and second annular gas flows where the second annular gas flow is arranged concentric to and radially outside of the first annular gas flow. The second annular gas flow is unaffected by tilting of the showerhead. Supplying more of the gas via the second annular gas flow as described below reduces sensitivity to changes in the first annular gas flow that occur due to tilting and that vary from one installation to another.

The processing chamber includes a chamber enclosure to confine process gases and/or plasma. The chamber enclosure includes an upper chamber surface 804, chamber sidewalls and a bottom chamber surface (both not shown). A first cavity 806 extends vertically through the upper chamber surface 804. As will be described further below, the back side gas system 801 supplies back side gas that is split into the first annular gas flow and the second annular gas flow that pass along radially outer surfaces of the showerhead 300 (e.g., the upper portion 310, the first cone-shaped portion 312 and the second cone-shaped portion 314). In some examples, the second annular gas flow supplies more gas to the back side volume 802 than the first annular gas flow.

A first annular support member 810 is arranged in the first cavity 806 of the upper chamber surface 804. The first annular support member 810 has a “T”-shaped cross section. The first annular support member 810 includes a second cavity 811 (passing vertically through the first annular support member 810), an upper annular portion 812, and a lower annular portion 814. In some embodiments, the first cavity 806 in the upper chamber surface 804 and the second annular support member 820 have complementary or mating facing surfaces.

In some embodiments, the upper annular portion 812 has an outer diameter that is greater than an outer diameter of the lower annular portion 814. The upper portion 310 of the showerhead 300 is arranged in the second cavity 811. The first annular support member 810 remains stationary relative to the first cavity 806 in the upper chamber surface 804 as the showerhead 300 is tilted within the second cavity 811. As a result, a side surface of the showerhead 300 moves closer to the first annular support member 810 causing restriction of the first annular gas flow in certain radial locations.

A second annular support member 820 is connected to an upper mounting surface (not shown). In some examples, the second annular support member 820 has a “T”-shaped cross section. The second annular support member 820 includes an annular upper portion 821, an annular lower portion 823 and a third cavity 825 passing vertically therethrough. The annular upper portion 821 has an outer diameter that is greater than an outer diameter of the annular lower portion 823. Fasteners 827 connect the second annular support member 820 to the upper portion 310 of the showerhead 300 and to an annular support plate 816. A stem portion 829 of the showerhead 300 passes through the third cavity 825 in the second annular support member 820 and is connected to the gas delivery system 800. The gas delivery system 800 supplies process gases to the gas channel and the gas plenum as described above.

The annular support plate 816 is mounted below the second annular support member 820. The upper annular portion 812 of the first annular support member 810 is connected by a tilting mechanism 830 to the annular support plate 816. The tilting mechanism 830 includes variable length legs allowing controlled tilting of the showerhead 300 within the second cavity 811 defined by the first annular support member 810. The tilting mechanism 830 allows fine adjustment of the tilt of the showerhead 300 (and the faceplate) relative to an upper surface of the substrate support. In some examples, the tilting mechanism 830 adjusts tilt in a range from 0° to 1°, although other ranges can be used.

A bellows 840 is arranged around a radially outer surface of the second annular support member 820 to define a flexible volume (or “bellows volume”) around the lower annular lower portion 823 of the second annular support member 820. The bellows 840 flexibly connects a lower and radially inner surface 841 of the annular support plate 816 to a radially inner and upwardly facing surface 843 of the first annular support member 810 to define the bellows volume. Back side gas is supplied to the bellows volume and split by the first annular support member 810 into first and second annular gas flows.

The radially inner surface of the upper annular portion 812 defines an annular opening 845 and an annular slanted surface 847 extending at an acute angle inwardly at or near a transition between the upper annular portion 812 and the lower annular portion 814. H channels 844 extend downwardly and outwardly through the upper annular portion 812 and/or the lower annular portion 814, where H is an integer greater than 4 and less than 60. In some examples, inlets of the H channels 844 are located on the annular slanted surface 847, although other locations can be used.

The H channels 844 extend from a radially inner surface of the first annular support member 810 to a radially outer surface of the first annular support member 810. The second annular gas flow is supplied by gas flowing through the H channels 844 into a radially outer annular gap 854 located between a radially outer surface of the lower annular portion 814 and a radially inner surface of the first cavity 806.

A protrusion 852 is formed on the radially inner surface of the first annular support member 810 at or near a transition between the upper annular portion 812 and the lower annular portion 814. The protrusion 852 restricts gas flow into a radially inner annular gap 850 located between the radially inner surface of the first annular support member 810 and a radially outer surface of the upper portion 310 of the showerhead 300.

Gas that is supplied to the bellows volume is split into the first and second gas flows. The first or radially inner gas flow flows past the protrusion 852 and into the radially inner annular gap 850. The second or radially outer gas flow passes through the H channels 844 and into the radially outer annular gap 854.

Referring now to FIG. 16, the tilting mechanism 830 and other features of the showerhead 300 are shown in further detail. In some examples, the tilting mechanism 830 includes height adjusting members 858 that have a variable length and extend from the second annular support member 820 through the annular support plate 816 to an upwardly-facing surface of the first annular support member 810. In some embodiments, the height adjusting members 858 include bolts received by threaded bores in the first annular support member 810. Turning the bolts increases or decreases a length of the height adjusting members 858 and a local distance separating the annular support plate 816 and the first annular support member 810.

In some examples, three of the height adjusting members 858 are spaced 120° apart. In other words, the height adjusting members 858 can be individually adjusted to cause a desired amount of height adjustment and/or tilt. The height of all of the height adjusting members 858 can be increased or decreased by the same amount to adjust a height of the faceplate above the substrate support. While manually adjusted height adjusting members such as bolts are shown, actuators (such as stepper motors or other adjusting devices) with projecting and retracting cylinders can be used.

Back side gas is supplied by the gas source 412 and the valve 414 to an inlet 862 of a vertical channel 860 extending downwardly through the second annular support member 820. The gas flows into an annular cavity 863 defined by the annular support plate 816 between the upper surface of the annular support plate 816 and a bottom surface of the second annular support member 820. In some embodiments, one or more O-rings (not shown) are used for sealing adjacent surfaces between two or more components. The gas flows downwardly through the vertical channel 860 into the annular cavity 863, radially inwardly, downwardly past a protrusion 866, and into the bellows volume. The protrusion 866 restricts the gas flow from the gas source into the bellows volume.

Referring now to FIGS. 16 and 17, the first annular support member 810 is shown in further detail. Cylindrical guides 910 extending from the first annular support member 810 pass through openings 912 in the annular support plate 816 as the height of the height adjusting members 858 is adjusted (FIG. 16). The cylindrical guides 910 allow relative movement (e.g., tilting) of the showerhead relative to the first annular support member 810. The height adjusting members 858 are received in the cylindrical guides 910. Guide pins 920 that are received by corresponding bores in the second annular support member 820 are used to align the annular support plate 816 relative to the second annular support member 820. A plurality of bores 941 pass vertically through the first annular portion 814 and receive fasteners (not shown) to attach the first annular support member 810 to the upper chamber surface 804 in the cavity 811.

Inlets of the H channels 844 are shown arranged around the annular slanted surface 847. One or more rotational alignment portions 930 may be defined in a groove 932 (e.g., a circular groove) located in an upwardly-facing surface 933 of the first annular support member 810. In some embodiments, the rotational alignment portions 930 include an arcuate portion 931 extending radially outwardly from the groove 932 to provide a detent. Additional rotational alignment portions can be arranged at different radial locations around the groove 932 relative to the rotational alignment portion 930 that is shown.

Referring back to FIG. 15, in some embodiments, a first flow rate of the first or radially inner gas flow passing through the radially inner annular gap 850 is less than a second flow rate of the second or radially outer gas passing through the radially outer annular gap 854. In some examples, the first flow is in a range from 10% to 40% of the back side gas supplied into the bellows volume and the second flow is in a range from 60% to 90% of the back side gas supplied into the bellows volume. In some examples, the first flow is in a range from 24% to 32% of the gas supplied into the bellows volume and the second flow is in a range from 68% to 76% of the gas supplied into the bellows volume. In other examples, the first and second annular gas flows are approximately equal or the first annular gas flow is greater than the second annular gas flow.

In some of the embodiments, more of the back side gas that is supplied to the bellows volume is split into the radially outer gas flow as compared to the radially inner gas flow. When the showerhead 300 is not tilted, spacing in the radially inner annular gap 850 is relatively uniform around the circumference of the first annular support member 810. As the showerhead 300 is tilted, the showerhead 300 moves relative to the first annular support member 810. The spacing in the radially inner annular gap 850 is smaller in some radial locations of the first annular support member 810, which alters the first gas flow to the back side volume. By splitting the back side gas into two annular gas flows and flowing more backside gas to the radially outer annular gas flow, the showerhead 300 reduces the impact of changes due to tilt. Radial uniformity of deposition is significantly less affected by tilting as compared to a showerhead providing only a single back side gas flow path.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A showerhead for a substrate processing system, comprising:
an upper portion including a gas channel extending in a first direction and having a first width in a second direction transverse to the first direction;
a lower portion connected to the upper portion and including:
a faceplate including a plurality of gas through holes extending vertically through the faceplate in the first direction; and
a baffle plate arranged on a plurality of posts above the faceplate and below an outlet of the gas channel, wherein the baffle plate includes a plurality of baffle orifices and has a second width in the second direction that is in a range from 1.25 to 3 times the first width; and
a gas plenum defined between the upper portion and the lower portion, extending in the second direction, and in fluid communication with the gas channel.

2. The showerhead of claim 1, wherein each of the plurality of baffle orifices is misaligned with ones of the plurality of gas through holes that are located below the baffle plate in the first direction.

3. The showerhead of claim 1, wherein the plurality of baffle orifices is arranged symmetrically relative to a center of the baffle plate.

4. The showerhead of claim 1, wherein the second width is in a range from 1.75 to 2.5 times the first width.

5. The showerhead of claim 1, wherein the plurality of gas through holes has a first diameter and the plurality of baffle orifices has a second diameter that is greater than the first diameter.

6. The showerhead of claim 5, wherein the second diameter is in a range from 1.2 to 6 times greater than the first diameter.

7. The showerhead of claim 5, wherein the second diameter is in a range from 1.5 to 3 times greater than the first diameter.

8. The showerhead of claim 1, wherein the upper portion includes:
a stem portion;
a first cone-shaped portion extending from the stem portion; and
a second cone-shaped portion extending from the first cone-shaped portion and including a radially outer edge attached to the lower portion.

9. The showerhead of claim 8, wherein:
a side surface of the first cone-shaped portion forms a first acute angle relative to a side surface of the stem portion;
a side surface of the second cone-shaped portion forms a second acute angle relative to a side surface of the stem portion; and
the first acute angle is less than the second acute angle.

10. The showerhead of claim 9, further comprising P posts connected between the faceplate and the second cone-shaped portion of the upper portion, wherein P is an integer greater than one.

11. The showerhead of claim 10, wherein P is in a range from 8 to 24.

12. The showerhead of claim 11, wherein P is equal to 12.

13. The showerhead of claim 11, wherein the P posts are arranged in a circle.

14. The showerhead of claim 11, wherein the P posts are arranged between a first radius corresponding to a radially inner edge of the second cone-shaped portion and a second radius corresponding to a radially outer edge of the second cone-shaped portion.

15. The showerhead of claim 8, wherein:
the gas channel has a first radius; and
a substrate-facing surface of the lower portion includes:
a rounded portion extending from the first radius to a second radius;
a first horizontal portion extending from the second radius to a third radius;
a tapered portion extending from the third radius to a fourth radius; and
a second horizontal portion extending from the fourth radius to a fifth radius.

16. The showerhead of claim 15, wherein the third radius is in a range from 0.75 to 2.5 times the second width.

17. The showerhead of claim 15, wherein the baffle plate is arranged between 25% and 75% of a distance between the first horizontal portion and the faceplate in the first direction.

18. The showerhead of claim 9, further comprising:
P access holes passing through the second cone-shaped portion of the upper portion; and
P posts connecting the faceplate to the second cone-shaped portion and extending into the P access holes, wherein P is an integer greater than one.

19. The showerhead of claim 1, wherein at least one of the baffle orifices at least partially overlaps at least one of the gas through holes in the first direction.

20. The showerhead of claim 1, wherein at least one of the baffle orifices fully overlaps at least one of the gas through holes in the first direction.

21. The showerhead of claim 1, wherein:
the gas through holes in the faceplate are arranged in a first zone and a second zone;
first ones of the plurality of gas through holes in the first zone have a first hole density;
second ones of the plurality of gas through holes arranged in the second zone have a second hole density; and
the second hole density is greater than the first hole density.

22. The showerhead of claim 21, wherein:
the first zone extends to a first radius;
the second zone extends from the first radius to a second radius; and
the first radius is greater than or equal to 0.7 times the second radius.

23. A showerhead assembly comprising:
the showerhead of claim 9; and
a back side gas system configured to supply gas in a downward and radially outward direction along the stem portion, the first cone-shaped portion, and the second cone-shaped portion.

24. A substrate processing system comprising
the showerhead assembly of claim 23;
a processing chamber including an upper surface defining a cavity;
an annular support arranged around the stem portion and in the cavity of the upper surface and including a radially inner surface and a radially outer surface;
a first annular gap formed between the radially outer surface of the annular support and the cavity in the upper surface of the processing chamber; and
a second annular gap formed between the radially inner surface of the annular support and the stem portion,
wherein the back side gas system supplies the gas to the first annular gap and the second annular gap.

25. A method for depositing film on a substrate, comprising:
delivering process gas to an exposed surface of the substrate using a showerhead arranged in a processing chamber, wherein the showerhead comprises:
an upper portion including a gas channel configured to receive the process gas, extending in a first direction and having a first width in a second direction transverse to the first direction;
a lower portion comprising a faceplate with a plurality of gas through holes extending through the faceplate in the first direction; and
a gas plenum defined between the upper portion and the lower portion and extending in the second direction; and
redirecting process gas exiting the gas channel using a baffle plate that is located below the gas channel in the gas plenum and above the faceplate and includes a plurality of baffle orifices extending through the baffle plate in the first direction,
wherein a first portion of the process gas is redirected from the first direction to the second direction by portions of the baffle plate without the plurality of baffle orifices,
wherein a second portion of the process gas passes through the plurality of orifices of the baffle plate and through ones of the plurality of gas through holes arranged below the baffle plate, and
wherein the baffle plate has a second width in the second direction that is in a range from 1.25 to 3 times the first width.

26. The method of claim 25, wherein the process gas includes at least one of a reactant and a precursor.

27. The method of claim 26, further comprising exposing the substrate to the at least one of the precursor and the reactant to form a dielectric material.

28. The method of claim 27, further comprising treating the dielectric material to a densification plasma to form a densified dielectric material.

29. A showerhead for a substrate processing system, comprising:
an upper portion including a stem portion, a first cone-shaped portion extending from the stem portion, a second cone-shaped portion extending from the first cone-shaped portion;
a gas channel extending through the upper portion in a first direction and having a first radius;
a lower portion including a radially outer edge connected to the upper portion, a faceplate including a plurality of gas through holes extending through the faceplate in the first direction, and a baffle plate arranged on a plurality of posts above the faceplate and including a plurality of baffle orifices extending through the baffle plate; and
a gas plenum defined between a first surface of the upper portion and the lower portion and extending in a second direction transverse to the first direction;
wherein the first surface of the upper portion includes a rounded portion extending from the first radius to a second radius, a first horizontal portion extending from the second radius to a third radius, a tapered portion extending at an acute angle from the third radius to a fourth radius, and a second horizontal portion extending from the fourth radius to a fifth radius.

30. A showerhead for a substrate processing system, comprising:
an upper portion including a stem portion, a first cone-shaped portion including a side surface extending from the stem portion at a first acute angle relative to a side surface of the stem portion, a second cone-shaped portion extending from the first cone-shaped portion and including a side surface forming a second acute angle relative to the side surface of the stem portion, and a gas channel extending through the upper portion in a first direction, wherein the second acute angle is greater than the first acute angle;
a lower portion including a radially outer edge connected to the upper portion, a faceplate including a plurality of gas through holes extending through the faceplate in the first direction, and a baffle plate arranged on a plurality of posts above the faceplate and including a plurality of baffle orifices extending through the baffle plate in the first direction; and
a gas plenum defined between the upper portion and the lower portion;
wherein the faceplate includes a first zone that extends to a first radius and a second zone that extends from the first radius to a second radius, first ones of the plurality of gas through holes arranged in the first zone have a first hole density, second ones of the plurality of gas through holes arranged in the second zone have a second hole density, and the second hole density is greater than the first hole density.

31. A showerhead assembly for a substrate processing system, comprising:
an upper portion including a stem portion, a first cone-shaped portion including a side surface extending from the stem portion at a first acute angle relative to a side surface of the stem portion, a second cone-shaped portion extending from the first cone-shaped portion and including a side surface forming a second acute angle relative to the side surface of the stem portion, and a gas channel extending in a first direction through the upper portion, wherein the second acute angle is greater than the first acute angle;
a lower portion including a radially outer edge connected to the upper portion, a faceplate including a plurality of gas through holes extending in the first direction through the faceplate, and a baffle plate arranged on a plurality of posts between the faceplate and the gas channel and including a plurality of baffle orifices extending through the baffle plate in the first direction;
a gas plenum defined between the upper portion and the lower portion and extending in a second direction transverse to the first direction; and
a back side gas system configured to supply gas along the stem portion, the first cone-shaped portion, and the second cone-shaped portion during substrate processing.

32. A showerhead assembly, comprising:
a processing chamber including an upper chamber surface defining a first cavity;
a showerhead including an upper portion, a lower portion including a faceplate, and a gas plenum arranged between the upper portion and the lower portion;
a first annular support member arranged in the first cavity and defining a second cavity configured to receive the upper portion of the showerhead,
wherein the first annular support member defines:
a first annular gap located between a radially inner surface of the second cavity and a radially outer surface of the upper portion of the showerhead; and
a second annular gap located between the radially outer surface of the first annular support member and a radially inner surface of the first cavity, and
wherein back side gas is split by the first annular support member into a first gas flow into the first annular gap and a second gas flow into the second annular gap.

33. The showerhead assembly of claim 32, wherein:
the first annular support member includes an upper annular portion and a lower annular portion extending downwardly from the upper annular portion;
the second cavity passes through the upper annular portion and the lower annular portion; and
the upper annular portion has an outer diameter that is greater than an outer diameter of the lower annular portion.

34. The showerhead assembly of claim 32, wherein the first annular support member includes a plurality of channels passing from a radially inner surface of the first annular support member to a radially outer surface of the first annular support member.

35. The showerhead assembly of claim 34, wherein the second gas flow passes through the plurality of channels to the second annular gap.

36. The showerhead assembly of claim 35, further comprising a first protrusion extending radially inwardly from the radially inner surface of the first annular support member to restrict flow of gas into the first annular gap.

37. The showerhead assembly of claim 32, further comprising:
a second annular support member including a gas channel;
an annular support plate connected to the second annular support member and including:
an annular opening in fluid communication with an outlet of the gas channel of the second annular support member; and
a first protrusion extending radially inwardly from a radially inner surface of the annular support plate towards an outer surface of the first annular support member to restrict flow of gas from the gas channel into the first annular gap and the second annular gap.

38. The showerhead assembly of claim 32, wherein the first gas flow through the first annular gap is less than the second gas flow through the second annular gap.

39. The showerhead assembly of claim 38, wherein the second gas flow is in a range from 60% to 90% of gas flowing through the first annular gap and the second annular gap and the first gas flow is in a range from 10% to 40% of the gas flowing through the first annular gap and the second annular gap.

40. The showerhead assembly of claim 38, wherein the second gas flow is in a range from 68% to 76% of gas flowing through the first annular gap and the second annular gap and the first gas flow is in a range from 24% to 32% of the gas flowing through the first annular gap and the second annular gap.

41. The showerhead assembly of claim 32, further comprising:
a tilt mechanism configured to tilt the showerhead relative to the first annular support member,
wherein when the tilt mechanism tilts the showerhead relative to a centered position, the first annular gap is narrowed at a first radial location.

42. The showerhead assembly of claim 37, further comprising a bellows arranged between a first surface of the first annular support member and a second surface of the annular support plate.

43. The showerhead assembly of claim 42, wherein:
the upper portion of the showerhead includes a stem portion, a first cone-shaped portion extending from the stem portion, and a second cone-shaped portion extending from the first cone-shaped portion, and
the first gas flow and the second gas flow are directed across the stem portion, the first cone-shaped portion, and the second cone-shaped portion.

44. The showerhead assembly of claim 43, wherein:
the first cone-shaped portion includes a side surface extending from the stem portion at a first acute angle relative to a side surface of the stem portion,
the second cone-shaped portion extends from the first cone-shaped portion and includes a side surface forming a second acute angle relative to the side surface of the stem portion; and
the second acute angle is greater than the first acute angle.

45. The showerhead assembly of claim 32, wherein:
the faceplate includes a plurality of gas through holes extending vertically through the faceplate in a first direction; and
the upper portion of the showerhead includes a gas channel extending in the first direction and having a first width in a second direction transverse to the first direction.

46. The showerhead assembly of claim 45, further comprising a baffle plate arranged on a plurality of posts above the faceplate and below an outlet of the gas channel, wherein the baffle plate includes a plurality of baffle orifices and has a second width in the second direction that is in a range from 1.25 to 3 times the first width.

47. The showerhead assembly of claim 46, wherein each of the plurality of baffle orifices is misaligned with ones of the plurality of gas through holes that are located below the baffle plate in the first direction.

48. The showerhead assembly of claim 46, wherein the plurality of baffle orifices is arranged symmetrically relative to a center of the baffle plate.

49. The showerhead assembly of claim 48, wherein the second width is in a range from 1.75 to 2.5 times the first width.

50. The showerhead assembly of claim 48, wherein the plurality of gas through holes has a first diameter and the plurality of baffle orifices has a second diameter that is greater than the first diameter.

51. The showerhead assembly of claim 50, wherein the second diameter is in a range from 1.2 to 6 times greater than the first diameter.

52. The showerhead assembly of claim 50, wherein the second diameter is in a range from 1.5 to 3 times greater than the first diameter.
